(19) United States
(12) Patent Application Publication
(10) Pub. No.: US 2018/0261748 A1
(43) Pub. Date: Sep. 13, 2018

(54) THERMOELECTRIC HEAT PUMP CASCADE USING MULTIPLE PRINTED CIRCUIT BOARDS WITH THERMOELECTRIC MODULES

(71) Applicant: Phononic, Inc., Durham, NC (US)

(72) Inventors: Brian J. Williams, Chapel Hill, NC (US); Devon Newman, Salt Lake City, UT (US); Abhishek Yadav, Cary, NC (US); Jason D. Reed, Chapel Hill, NC (US); Kevin S. Schneider, Cary, NC (US); Jesse W. Edwards, Wake Forest, NC (US)

(21) Appl. No.: 15/917,282

(22) Filed: Mar. 9, 2018

Related U.S. Application Data
(60) Provisional application No. 62/469,992, filed on Mar. 10, 2017.
(60) Provisional application No. 62/472,311, filed on Mar. 16, 2017.

(51) Int. Cl. H01L 35/30; H01L 35/32; H01L 23/38

(52) U.S. Cl. CPC H01L 35/30; H01L 23/38; H01L 35/32

(57) ABSTRACT

A thermoelectric heat pump cascade and a method of manufacturing such are disclosed herein. In some embodiments, a thermoelectric heat pump cascade includes a first stage plurality of thermoelectric devices attached to a first stage circuit board and a first stage thermal interface material between the thermoelectric devices and the heat spreading lid over the thermoelectric devices. The thermoelectric heat pump cascade component also includes a second stage plurality of thermoelectric devices attached to a second stage circuit board where the second stage plurality of thermoelectric devices has a greater heat pumping capacity than the first stage plurality of thermoelectric devices, and a second stage thermal interface material between the second stage plurality of thermoelectric devices and the first stage plurality of thermoelectric devices. In this way, a greater temperature difference can be achieved while allowing for protection of the thermoelectric devices, simplifying design, and improving reliability of the product.

### RELATED APPLICATIONS

This application claims the benefit of provisional patent application Ser. No. 62/469,992, filed Mar. 10, 2017 and provisional patent application Ser. No. 62/472,311, filed Mar. 16, 2017, the disclosures of which are hereby incorporated herein by reference in their entireties.

### FIELD OF THE DISCLOSURE

The present disclosure relates to thermoelectric devices and their manufacture.

### BACKGROUND

Thermoelectric devices are solid state semiconductor devices that, depending on the particular application, can be either Thermoelectric Coolers (TECs) or Thermoelectric Generators (TEGs). TECs are solid state semiconductor devices that utilize the Peltier effect to transfer heat from one side of the device to the other, thereby creating a cooling effect on the cold side of the device. Because the direction of heat transfer is determined by the polarity of an applied voltage, thermoelectric devices can be used generally as temperature controllers. Similarly, TEGs are solid state semiconductor devices that utilize the Seebeck effect to convert heat (i.e., a temperature difference from one side of the device to the other) directly into electrical energy. A thermoelectric device includes at least one N-type leg and at least one P-type leg. The N-type legs and the P-type legs are formed of a thermoelectric material (i.e., a semiconductor material having sufficiently strong thermoelectric properties). In order to effect thermoelectric cooling, an electrical current is applied to the thermoelectric device. The direction of current transference in the N-type legs and the P-type legs is parallel to the direction of heat transference in the thermoelectric device. As a result, cooling occurs at the top surface of the thermoelectric device, and the heat is released at the bottom surface of the thermoelectric device.

Thermoelectric systems that use thermoelectric devices are advantageous compared to non-thermoelectric systems because they lack moving mechanical parts, have long lifespans, and can have small sizes and flexible shapes. However, there remains a need for thermoelectric devices with increased performance and longer lifespans.

### SUMMARY

A thermoelectric heat pump cascade and a method of manufacturing such are disclosed herein. In some embodiments, a thermoelectric heat pump cascade component includes a first stage plurality of thermoelectric devices attached to a first stage circuit board and a first stage thermal interface material between the first stage plurality of thermoelectric devices and the first stage heat spreading lid over the first stage plurality of thermoelectric devices. The thermoelectric heat pump cascade component also includes a second stage plurality of thermoelectric devices attached to a second stage circuit board where the second stage plurality of thermoelectric devices has a greater heat pumping capacity than the first stage plurality of thermoelectric devices, and a second stage thermal interface material between the second stage plurality of thermoelectric devices and the first stage plurality of thermoelectric devices. In this way, a greater temperature difference can be achieved while using a modular approach inside the heat pump allows for protection of the thermoelectric devices, simplifies design to mitigate manufacturing tolerance stack-up challenges, and greatly improves reliability of the product.

In some embodiments, the thermoelectric heat pump cascade component also includes a second stage heat spreading lid over the second stage plurality of thermoelectric devices and the second stage thermal interface material is between the second stage heat spreading lid and the first stage plurality of thermoelectric devices.

In some embodiments, the first stage plurality of thermoelectric devices contains a same number of thermoelectric devices as the second stage plurality of thermoelectric devices and the second stage plurality of thermoelectric devices has a greater heat pumping capacity than the first stage plurality of thermoelectric devices because each thermoelectric device of the second stage plurality of thermoelectric devices has a greater heat pumping capacity than a respective thermoelectric device of the first stage plurality of thermoelectric devices.

In some embodiments, the first stage plurality of thermoelectric devices contains fewer thermoelectric devices than the second stage plurality of thermoelectric devices. In some embodiments, each thermoelectric device of the second stage plurality of thermoelectric devices has the same heat pumping capacity as each thermoelectric device of the first stage plurality of thermoelectric devices.

In some embodiments, two or more of the first stage plurality of thermoelectric devices have different heights relative to the first stage circuit board and an orientation of the first stage heat spreading lid is such that a thickness of the first stage thermal interface material is optimized for the first stage plurality of thermoelectric devices.

In some embodiments, two or more of the second stage plurality of thermoelectric devices have different heights relative to the second stage circuit board and an orientation of the second stage heat spreading lid is such that a thickness of the second stage thermal interface material is optimized for the second stage plurality of thermoelectric devices.

In some embodiments, the first stage thermal interface material is solder or thermal grease.

In some embodiments, the first stage heat spreading lid also includes a lip that extends from a body of the first stage heat spreading lid around a periphery of the first stage heat spreading lid.

In some embodiments, a height of the lip relative to the body of the first stage heat spreading lid is such that, for any combination of heights of the first stage plurality of thermoelectric devices within a predefined tolerance range, at least a predefined minimum gap is maintained between the lip of the first stage heat spreading lid and a first surface of the first stage circuit board, wherein the predefined minimum gap is greater than zero.

In some embodiments, the thermoelectric heat pump cascade component also includes an attach material that fills the at least the predefined minimum gap between the lip of the first stage heat spreading lid and the first surface of the first stage circuit board around the periphery of the first stage heat spreading lid.

In some embodiments, the lip of the first stage heat spreading lid and the attach material absorb force applied to the first stage heat spreading lid so as to protect the first stage plurality of thermoelectric devices. In some embodiments, the attach material is an epoxy or a resin.

In some embodiments, the second stage heat spreading lid also includes a lip that extends from a body of the second stage heat spreading lid around a periphery of the second stage heat spreading lid.

In some embodiments, a height of the lip relative to the body of the second stage heat spreading lid is such that, for any combination of heights of the second stage plurality of thermoelectric devices within a predefined tolerance range, at least a predefined minimum gap is maintained between the lip of the second stage heat spreading lid and a first surface of the second stage circuit board, wherein the predefined minimum gap is greater than zero.

In some embodiments, the thermoelectric heat pump cascade component also includes an attach material that fills the at least the predefined minimum gap between the lip of the second stage heat spreading lid and the first surface of the second stage circuit board around the periphery of the second stage heat spreading lid.

In some embodiments, the lip of the second stage heat spreading lid and the attach material absorb force applied to the second stage heat spreading lid so as to protect the second stage plurality of thermoelectric devices. In some embodiments, the attach material is an epoxy or a resin.

In some embodiments, a method of fabricating a thermoelectric heat pump cascade component includes attaching a first stage plurality of thermoelectric devices to a first stage circuit board and applying a first stage thermal interface material between the first stage plurality of thermoelectric devices and a first stage heat spreading lid. The method also includes attaching a second stage plurality of thermoelectric devices to a second stage circuit board and applying a second stage thermal interface material between the first stage plurality of thermoelectric devices and the second stage plurality of thermoelectric devices.

In some embodiments, the method of fabricating also includes attaching a second stage heat spreading lid over the second stage plurality of thermoelectric devices and applying the second stage thermal interface material includes applying the second stage thermal interface material between the second stage heat spreading lid and the first stage plurality of thermoelectric devices.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a thermoelectric refrigeration system having a cooling chamber, a heat exchanger including at least one Thermoelectric Module (TEM) disposed between a cold side heat sink and a hot side heat sink, and a controller that controls the TEM according to some embodiments of the present disclosure;

FIG. 2 illustrates a side view of a Thermoelectric Component (TEC);

FIG. 3 illustrates a side view of a thermoelectric heat exchanger module;

FIG. 4 illustrates a thermoelectric heat pump cascade using multiple printed circuit boards with thermoelectric modules, according to some embodiments of the present disclosure;

FIG. 5 illustrates a thermoelectric heat pump cascade using the same type of thermoelectric modules in two stages, according to some embodiments of the present disclosure;

FIG. 6 illustrates a thermoelectric heat pump cascade using the same type of thermoelectric modules in three stages, according to some embodiments of the present disclosure;

FIG. 7 illustrates a thermoelectric heat pump cascade using different types of thermoelectric modules in each of two stages, according to some embodiments of the present disclosure; and

FIG. 8 illustrates a process for manufacturing a thermoelectric heat pump cascade using multiple printed circuit boards with thermoelectric modules of FIG. 4, according to some embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

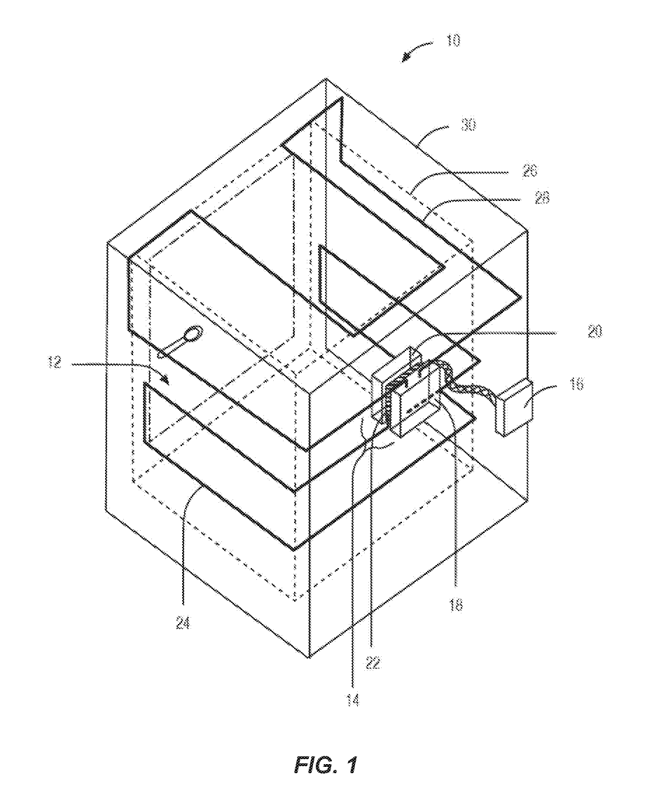

FIG. 1 illustrates a thermoelectric refrigeration system 10 having a cooling chamber 12, a heat exchanger 14 including at least one Thermoelectric Module (TEM) 22 (referred to herein singularly as TEM 22 or plural as TEMs 22) disposed between a cold side heat sink 20 and a hot side heat sink 18, and a controller 16 that controls the TEM 22 according to some embodiments of the present disclosure. When a TEM 22 is used to provide cooling it may sometimes be referred to as a Thermoelectric Cooler (TEC) 22.

The TEMs 22 are preferably thin film devices. When one or more of the TEMs 22 are activated by the controller 16, the activated TEMs 22 operate to heat the hot side heat sink 18 and cool the cold side heat sink 20 to thereby facilitate heat transfer to extract heat from the cooling chamber 12. More specifically, when one or more of the TEMs 22 are activated, the hot side heat sink 18 is heated to thereby create an evaporator and the cold side heat sink 20 is cooled to thereby create a condenser, according to some embodiments of the current disclosure.

Acting as a condenser, the cold side heat sink 20 facilitates heat extraction from the cooling chamber 12 via an accept loop 24 coupled with the cold side heat sink 20. The accept loop 24 is thermally coupled to an interior wall 26 of the thermoelectric refrigeration system 10. The interior wall 26 defines the cooling chamber 12. In one embodiment, the accept loop 24 is either integrated into the interior wall 26 or integrated directly onto the surface of the interior wall 26. The accept loop 24 is formed by any type of plumbing that allows for a cooling medium (e.g., a two-phase coolant) to flow or pass through the accept loop 24. Due to the thermal coupling of the accept loop 24 and the interior wall 26, the cooling medium extracts heat from the cooling chamber 12 as the cooling medium flows through the accept loop 24. The accept loop 24 may be formed of, for example, copper tubing, plastic tubing, stainless steel tubing, aluminum tubing, or the like.

Acting as an evaporator, the hot side heat sink 18 facilitates rejection of heat to an environment external to the cooling chamber 12 via a reject loop 28 coupled to the hot side heat sink 18. The reject loop 28 is thermally coupled to an outer wall 30, or outer skin, of the thermoelectric refrigeration system 10.

The thermal and mechanical processes for removing heat from the cooling chamber 12 are not discussed further. Also, it should be noted that the thermoelectric refrigeration system 10 shown in FIG. 1 is only a particular embodiment of a use and control of a TEM 22. All embodiments discussed herein should be understood to apply to thermoelectric refrigeration system 10 as well as any other use of a TEM 22.

Continuing with the example embodiment illustrated in FIG. 1, the controller 16 operates to control the TEMs 22 in order to maintain a desired set point temperature within the cooling chamber 12. In general, the controller 16 operates to selectively activate/deactivate the TEMs 22, selectively control an amount of power provided to the TEMs 22, and/or selectively control a duty cycle of the TEMs 22 to maintain the desired set point temperature. Further, in preferred embodiments, the controller 16 is enabled to separately or independently control one or more and, in some embodiments, two or more subsets of the TEMs 22, where each subset includes one or more different TEMs 22. Thus, as an example, if there are four TEMs 22, the controller 16 may be enabled to separately control a first individual TEM 22, a second individual TEM 22, and a group of two TEMs 22. By this method, the controller 16 can, for example, selectively activate one, two, three, or four TEMs 22 independently, at maximized efficiency, as demand dictates.

It should be noted that the thermoelectric refrigeration system 10 is only an example implementation and that the systems and methods disclosed herein are applicable to other uses of thermoelectric devices as well.

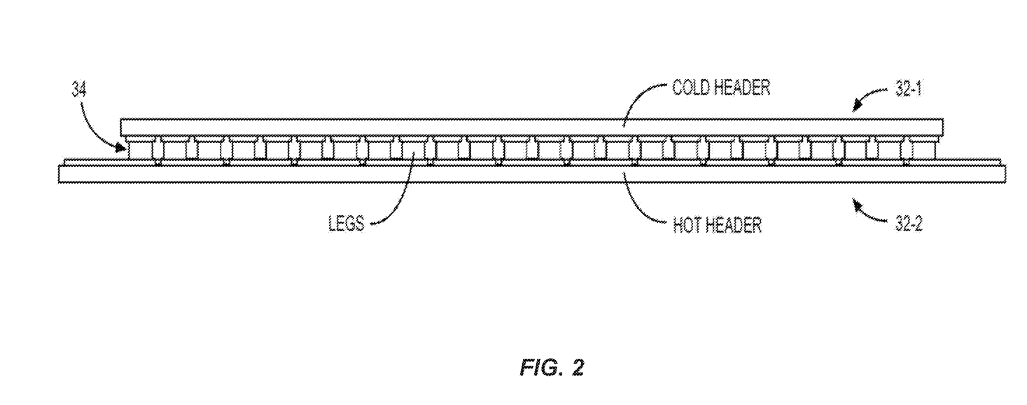

A common thermoelectric device such as a TEM 22 is shown in FIG. 2. The thermoelectric device consists of two headers 32, commonly referred to as cold header 32-1 and a hot header 32-2, and a series of legs 34 that are soldered to each header. In some embodiments, the headers 32 are made of ceramic. When the thermoelectric device is operated, heat is moved from the cold header 32-1 to the hot header 32-2, causing a temperature difference between the headers 32. This temperature difference results in thermal expansion and contraction of each header.

There is a need for systems and methods for minimizing the thermal resistance of the thermal interface material between thin film thermoelectric devices while also protecting the thin film thermoelectric devices from mechanical loading.

U.S. Pat. No. 8,893,513, the disclosure of which is hereby incorporated herein by reference in its entirety, details a method to encapsulate multiple thermoelectric devices on a circuit board with protective heat spreading lids and optimal thermal interface resistance. Although the method is advantageous for various applications, the design requires multiple interfaces and components.

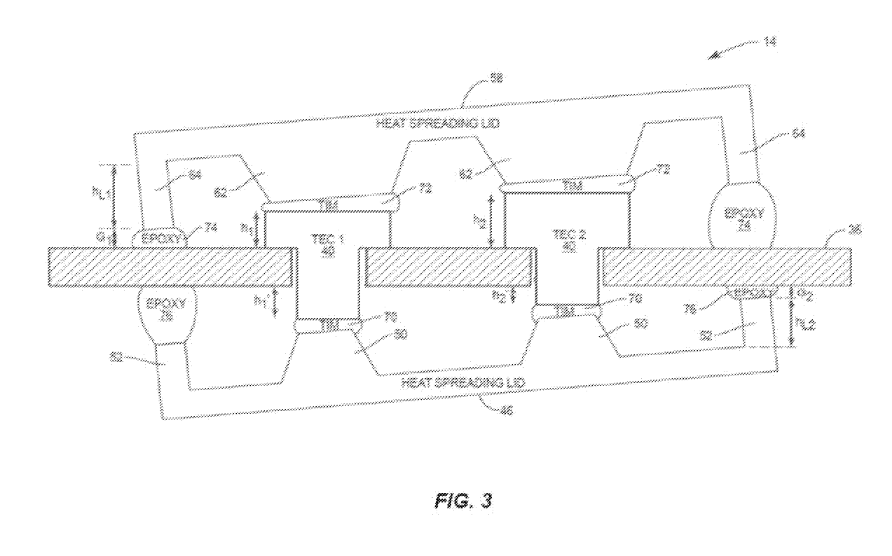

FIG. 3 illustrates a side view of a thermoelectric heat exchanger module such as heat exchanger 14 shown in FIG. 1. Heat spreading lids 46 and 58 enable the thermal interface resistance at the interfaces between the heat spreading lids 46 and 58 and TECs 40 to be optimized. More specifically, as illustrated in FIG. 3, heights of two or more of the TECs 40 may vary. Using conventional techniques to attach the TECs 40 to the hot side and/or the cold side heat sinks 18 and 20 would result in a less than optimal thermal interface resistance for shorter TECs 40 because there would be a larger amount of thermal interface material between those shorter TECs 40 and the corresponding heat sink 18, 20. In contrast, the structure of the heat spreading lids 46 and 58 enables an orientation (i.e., tilt) of the heat spreading lids 46 and 58 to be adjusted to optimize the thickness of Thermal Interface Material (TIM) 70, 72, and thus the thermal interface resistance, between pedestals 50, 62 and the corresponding surfaces of the TECs 40.

In this example, TEC 1 has a height (h1) relative to the first surface of a circuit board 36 that is less than a height (h2) of TEC 2 relative to the first surface of the circuit board 36. As discussed below in detail, when the heat spreading lid 58 is positioned over the TECs 40, a ball point force (i.e., a force applied via a ball point) is applied to a center of the heat spreading lid 58. As a result, the heat spreading lid 58 settles at an orientation that optimizes a thickness of the thermal interface material 72 between each of the pedestals 62 and the corresponding TEC 40.

A height (hL1) of a lip 64 of the heat spreading lid 58 is such that, for any possible combination of heights (h1 and h2) with a predefined tolerance range for the heights of the TECs 40 relative to the first surface of the circuit board 36, a gap (G1) between the lip 64 and the circuit board 36 is greater than a predefined minimum gap. The predefined minimum gap is a non-zero value. In one particular embodiment, the predefined minimum gap is a minimum gap needed for an epoxy and/or resin 74 to fill the gap (G1) while maintaining a predefined amount of pressure or force between the heat spreading lid 58 and TECs 40. Specifically, the height (hL1) of the lip 64 is greater than a minimum possible height of the TECs 40 relative to the first surface of the circuit board 36 plus the height of the pedestals 62, plus a predefined minimum height of the thermal interface material 72, plus some additional value that is a function of a maximum possible angle of the heat spreading lid 58 (which is a function of the minimum and maximum possible heights of the TECs 40) and a distance between the lip 64 and the nearest pedestal 62. In this embodiment, by adjusting the orientation of the heat spreading lid 58, the thickness of the thermal interface material 72, and thus the thermal interface resistance, for each of the TECs 40 is minimized.

In a similar manner, TEC 1 has a height (h1′) relative to the second surface of the circuit board 36 that is greater than a height (h2′) of TEC 2 relative to the second surface of the circuit board 36. As discussed below in detail, when the heat spreading lid 46 is positioned over the TECs 40, a ball point force (i.e., a force applied via a ball point) is applied to a center of the heat spreading lid 46. As a result, the heat spreading lid 46 settles at an orientation that optimizes a thickness of the thermal interface material 70 between each of the pedestals 50 and the corresponding TEC 40.

A height (hL2) of a lip 52 of the heat spreading lid 46 is such that, for any possible combination of heights (h1′ and h2′) with a predefined tolerance range for the heights of the TECs 40 relative to the second surface of the circuit board 36, a gap (G2) between the lip 52 and the circuit board 36 is greater than a predefined minimum gap. The predefined minimum gap is a non-zero value. In one particular embodiment, the predefined minimum gap is a minimum gap needed for an epoxy and/or resin 76 to fill the gap (G2) while maintaining a predefined amount of pressure or force between the heat spreading lid 46 and TECs 40. Specifically, the height (hL2) of the lip 52 is greater than a minimum possible height of the TECs 40 relative to the second surface of the circuit board 36 plus the height of the pedestals 50, plus a predefined minimum height of the thermal interface material 70, plus some additional value that is a function of a maximum possible angle of the heat spreading lid 46 (which is a function of the minimum and maximum possible heights of the TECs 40) and a distance between the lip 52 and the nearest pedestal 50. In this embodiment, by adjusting the orientation of the heat spreading lid 46, the thickness of the thermal interface material 70, and thus the thermal interface resistance, for each of the TECs 40 is minimized.

In the embodiment of FIG. 3, the dimensions of the pedestals 50 and 62 are slightly less than the dimensions of the corresponding surfaces of the TECs 40 at the interfaces between the pedestals 50 and 62 and the corresponding surfaces of the TECs 40. As such, when applying the ball point force to the heat spreading lids 46 and 58, the excess thermal interface material 70 and 72 moves along the edges of the pedestals 50 and 62 and is thereby prevented from thermally shorting the legs of the TECs 40. It should also be pointed out that any force applied to the heat spreading lid 46 is absorbed by the lip 52, the epoxy and/or resin 76, and the circuit board 36, which thereby protects the TECs 40. Likewise, any force applied to the heat spreading lid 58 is absorbed by the lip 64, the epoxy and/or resin 74, and the circuit board 36, which thereby protects the TECs 40. In this manner, significantly more even and uneven forces can be applied to the thermoelectric heat exchanger component 14 without damaging the TECs 40 as compared to a comparable heat exchanger component without the heat spreading lids 46 and 58.

U.S. Pat. No. 8,893,513 details a method to encapsulate multiple thermoelectric devices on a circuit board with protective heat spreading lids and optimal thermal interface resistance. Although the method is sufficient for various applications the design is limited in temperature range (DTmax) based upon the capability of single stage TEC modules.

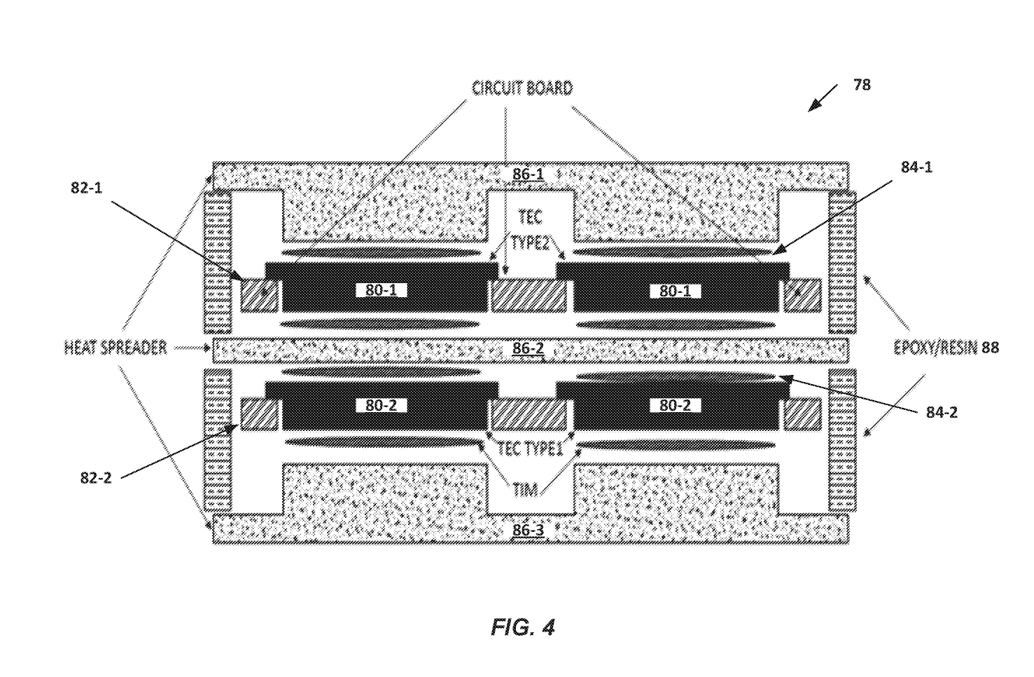

A thermoelectric heat pump cascade and a method of manufacturing such are disclosed herein. As shown in FIG. 4, a thermoelectric heat pump cascade component 78 includes a first stage plurality of thermoelectric devices 80-1 attached to a first stage circuit board 82-1 and a first stage thermal interface material 84-1 between the first stage plurality of thermoelectric devices 80-1 and the first stage heat spreading lid 86-1 over the first stage plurality of thermoelectric devices 80-1. The thermoelectric heat pump cascade component 78 also includes a second stage plurality of thermoelectric devices 80-2 attached to a second stage circuit board 82-2 where the second stage plurality of thermoelectric devices 80-2 has a greater heat pumping capacity than the first stage plurality of thermoelectric devices 80-1, and a second stage thermal interface material 84-2 between the second stage plurality of thermoelectric devices 80-2 and the first stage plurality of thermoelectric devices 80-1. In this way, a greater temperature difference can be achieved, while using a modular approach inside the thermoelectric heat pump cascade component 78 allows for protection of the thermoelectric devices (80-1 and 80-2), simplifies design to mitigate manufacturing tolerance stack-up challenges, and greatly improves reliability of the product. FIG. 4 shows a two stage thermoelectric heat pump cascade component 78 but this can be scaled easily for more circuit boards 82 inside depending upon the design application and requirements.

FIG. 4 shows an optional a second stage heat spreading lid 86-2 over the second stage plurality of thermoelectric devices 80-2. When this is used, the second stage thermal interface material 84-2 is between the second stage heat spreading lid 86-2 and the first stage plurality of thermoelectric devices 80-1.

FIG. 4 also shows the optional attach material 88 that fills the at least the gap between the lip of the first stage heat spreading lid 86-1 and the first surface of the first stage circuit board 82-1 around the periphery of the first stage heat spreading lid 86-1. In some embodiments, this attach material can be an epoxy or a resin.

In some embodiments, each circuit board 82 has some type of external input/output for power. To compensate for the additional heat that needs to be extracted by the lower stages, the different stages will have either different quantities of the same thermoelectric device type or different thermoelectric device types with the same quantity of thermoelectric devices to enable the cascade approach.

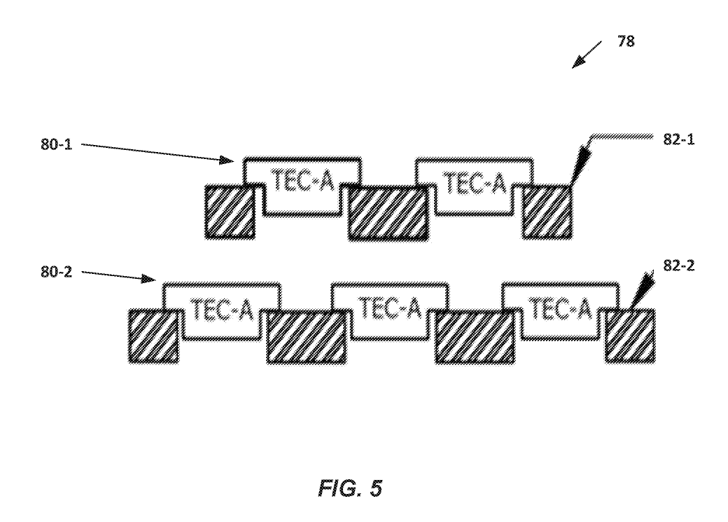

FIG. 5 illustrates a thermoelectric heat pump cascade component 78 using the same type of thermoelectric devices 80 in two stages, according to some embodiments of the present disclosure. FIG. 5 shows the basic structure without all of the other heat pump materials from FIG. 4. The cascade method is enabled by each lower stage to having more thermoelectric devices 80 than the one above it in order to pump more energy. Specifically, a first stage circuit board 82-1 has a total of two first stage thermoelectric devices 80-1 while a second stage circuit board 82-2 has a total of three second stage thermoelectric devices 80-2. This permits the second stage to remove the heat that the first stage removes along with the additional heat generated by the first stage.

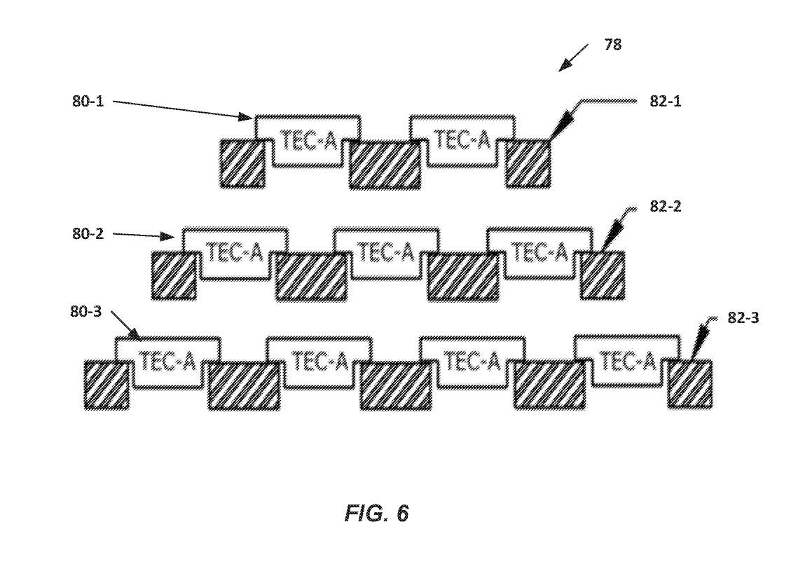

As discussed above, this thermoelectric heat pump cascade component 78 can be scaled easily for more circuit boards 82 inside depending upon the design application and requirements. FIG. 6 illustrates a thermoelectric heat pump cascade component 78 using the same type of thermoelectric devices 80 in three stages, according to some embodiments of the present disclosure. Similar to FIG. 5, a first stage circuit board 82-1 has a total of two first stage thermoelectric devices 80-1 while a second stage circuit board 82-2 has a total of three second stage thermoelectric devices 80-2. The additional third stage includes a third stage circuit board 82-3 that has a total of four third stage thermoelectric devices 80-3. These numbers are only for illustration.

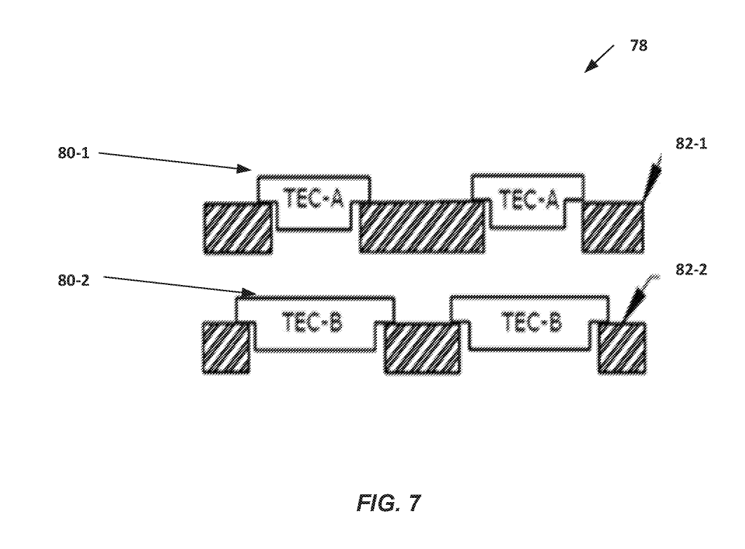

As discussed above, the different stages could also have a greater heat pumping capacity by being a different type of thermoelectric device 80. FIG. 7 illustrates a thermoelectric heat pump cascade component 78 using different types of thermoelectric devices 80 in each of two stages, according to some embodiments of the present disclosure. As shown, a first stage circuit board 82-1 has a total of two first stage thermoelectric devices 80-1 of type A while a second stage circuit board 82-2 also has a total of two second stage thermoelectric devices 80-2, but these are of type B. In this embodiment, the type B thermoelectric devices 80-2 have a greater heat pumping capacity to remove the heat that the first stage removes along with the additional heat generated by the first stage.

There are many different design techniques to realize the different types of thermoelectric devices 80 (material types, geometry), but the key is that the lower stages must be capable of transferring more energy (Q) than the stage before it. Otherwise stated type B (Q) must be greater than type A (Q) such that type B thermoelectric devices can transfer the energy created by the type A thermoelectric devices in addition to the amount of Q desired to transfer through the entire system under the desired application conditions.

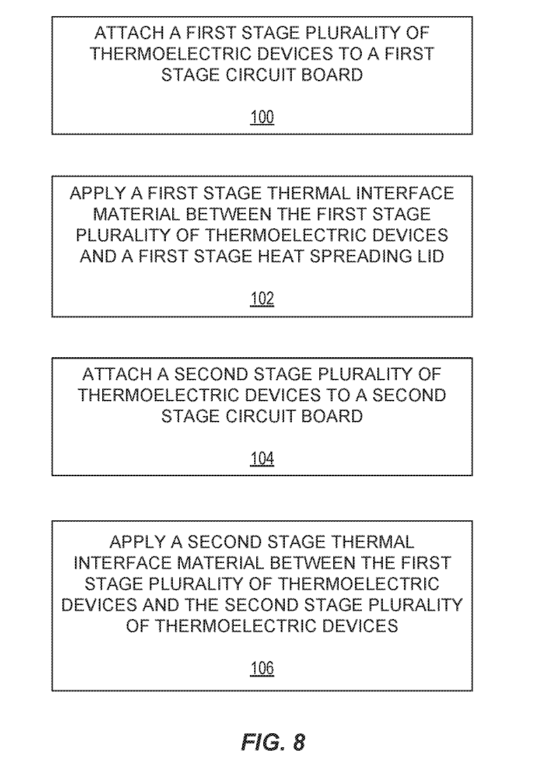

FIG. 8 illustrates a process for manufacturing a thermoelectric heat pump cascade component 78 of FIG. 4, according to some embodiments of the present disclosure. First, a first stage plurality of thermoelectric devices 80-1 is attached to a first stage circuit board 82-1 (step 100). Next, a first stage thermal interface material 84-1 is applied between the first stage plurality of thermoelectric devices 82-1 and a first stage heat spreading lid 86-1 (step 102). A second stage plurality of thermoelectric devices 82-2 is attached to a second stage circuit board 82-2 (step 104). Then, a second stage thermal interface material 84-2 is applied between the first stage plurality of thermoelectric devices 80-1 and the second stage plurality of thermoelectric devices 80-2 (step 106).

In some embodiments, the process optionally includes attaching a second stage heat spreading lid 86-2 over the second stage plurality of thermoelectric devices 80-2. In this case, the second stage thermal interface material 84-2 is applied between the second stage heat spreading lid 86-2 and the first stage plurality of thermoelectric devices 80-1.

Those skilled in the art will recognize improvements and modifications to the preferred embodiments of the present disclosure. All such improvements and modifications are considered within the scope of the concepts disclosed herein and the claims that follow.

What is claimed is:

1. A thermoelectric heat pump cascade component, comprising:
a first stage circuit board;
a first stage plurality of thermoelectric devices attached to the first stage circuit board;
a first stage heat spreading lid over the first stage plurality of thermoelectric devices;
a first stage thermal interface material between the first stage plurality of thermoelectric devices and the first stage heat spreading lid;
a second stage circuit board;
a second stage plurality of thermoelectric devices attached to the second stage circuit board where the second stage plurality of thermoelectric devices has a greater heat pumping capacity than the first stage plurality of thermoelectric devices; and
a second stage thermal interface material between the second stage plurality of thermoelectric devices and the first stage plurality of thermoelectric devices.

2. The thermoelectric heat pump cascade component of claim 1 further comprising:
a second stage heat spreading lid over the second stage plurality of thermoelectric devices; and
wherein the second stage thermal interface material is between the second stage heat spreading lid and the first stage plurality of thermoelectric devices.

3. The thermoelectric heat pump cascade component of claim 1 wherein:
the first stage plurality of thermoelectric devices contains a same number of thermoelectric devices as the second stage plurality of thermoelectric devices; and
the second stage plurality of thermoelectric devices has a greater heat pumping capacity than the first stage plurality of thermoelectric devices because each thermoelectric device of the second stage plurality of thermoelectric devices has a greater heat pumping capacity than a respective thermoelectric device of the first stage plurality of thermoelectric devices.

4. The thermoelectric heat pump cascade component of claim 1 wherein:
the first stage plurality of thermoelectric devices contains fewer thermoelectric devices than the second stage plurality of thermoelectric devices.

5. The thermoelectric heat pump cascade component of claim 4 wherein:
each thermoelectric device of the second stage plurality of thermoelectric devices has a same heat pumping capacity as each thermoelectric device of the first stage plurality of thermoelectric devices.

6. The thermoelectric heat pump cascade component of claim 1 wherein:
two or more of the first stage plurality of thermoelectric devices have different heights relative to the first stage circuit board; and
an orientation of the first stage heat spreading lid is such that a thickness of the first stage thermal interface material is optimized for the first stage plurality of thermoelectric devices.

7. The thermoelectric heat pump cascade component of claim 2 wherein:
two or more of the second stage plurality of thermoelectric devices have different heights relative to the second stage circuit board; and
an orientation of the second stage heat spreading lid is such that a thickness of the second stage thermal interface material is optimized for the second stage plurality of thermoelectric devices.

8. The thermoelectric heat pump cascade component of claim 1 wherein the first stage thermal interface material is chosen from the group consisting of: solder and thermal grease.

9. The thermoelectric heat pump cascade component of claim 1 wherein the first stage heat spreading lid further comprises a lip that extends from a body of the first stage heat spreading lid around a periphery of the first stage heat spreading lid.

10. The thermoelectric heat pump cascade component of claim 9 wherein a height of the lip relative to the body of the first stage heat spreading lid is such that, for any combination of heights of the first stage plurality of thermoelectric devices within a predefined tolerance range, at least a predefined minimum gap is maintained between the lip of the first stage heat spreading lid and a first surface of the first stage circuit board, wherein the predefined minimum gap is greater than zero.

11. The thermoelectric heat pump cascade component of claim 10 further comprising an attach material that fills the at least the predefined minimum gap between the lip of the first stage heat spreading lid and the first surface of the first stage circuit board around the periphery of the first stage heat spreading lid.

12. The thermoelectric heat pump cascade component of claim 11 wherein the lip of the first stage heat spreading lid and the attach material absorb force applied to the first stage heat spreading lid so as to protect the first stage plurality of thermoelectric devices.

13. The thermoelectric heat pump cascade component of claim 11 wherein the attach material is chosen from the group consisting of: an epoxy and a resin.

14. The thermoelectric heat pump cascade component of claim 2 wherein the second stage heat spreading lid further comprises a lip that extends from a body of the second stage heat spreading lid around a periphery of the second stage heat spreading lid.

15. The thermoelectric heat pump cascade component of claim 14 wherein a height of the lip relative to the body of the second stage heat spreading lid is such that, for any combination of heights of the second stage plurality of thermoelectric devices within a predefined tolerance range, at least a predefined minimum gap is maintained between the lip of the second stage heat spreading lid and a first surface of the second stage circuit board, wherein the predefined minimum gap is greater than zero.

16. The thermoelectric heat pump cascade component of claim 15 further comprising an attach material that fills the at least the predefined minimum gap between the lip of the second stage heat spreading lid and the first surface of the second stage circuit board around the periphery of the second stage heat spreading lid.

17. The thermoelectric heat pump cascade component of claim 16 wherein the lip of the second stage heat spreading lid and the attach material absorb force applied to the second stage heat spreading lid so as to protect the second stage plurality of thermoelectric devices.

18. The thermoelectric heat pump cascade component of claim 16 wherein the attach material is chosen from the group consisting of: an epoxy and a resin.

19. A method of fabricating a thermoelectric heat pump cascade component, comprising:
attaching a first stage plurality of thermoelectric devices to a first stage circuit board;
applying a first stage thermal interface material between the first stage plurality of thermoelectric devices and a first stage heat spreading lid;
attaching a second stage plurality of thermoelectric devices to a second stage circuit board; and
applying a second stage thermal interface material between the first stage plurality of thermoelectric devices and the second stage plurality of thermoelectric devices.

20. The method of claim 19 further comprising:
attaching a second stage heat spreading lid over the second stage plurality of thermoelectric devices; and
wherein applying the second stage thermal interface material comprises applying the second stage thermal interface material between the second stage heat spreading lid and the first stage plurality of thermoelectric devices.
